(19) United States
(12) Patent Application Publication
(10) Pub. No.: US 2026/0296878 A1
(43) Pub. Date: Oct. 1, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Nick Renaud-Bezot, Munich (DE); Lawrence Natan, Chandler, AZ (US)

(73) Assignee: Amkor Technology Singapore Holding Pte. Ltd., (omitted)

(21) Appl. No.: 19/091,243

(22) Filed: Mar. 26, 2025

(51) Int. Cl. B81B 7/00; B81C 1/00; H04R 19/00; H04R 19/02

(52) U.S. Cl. CPC B81B 7/0061; B81C 1/00269; H04R 19/005; H04R 19/02; B81B 2201/0257; B81B 2203/0315; B81B 2207/03; B81B 2207/07; B81C 2203/0109

(57) ABSTRACT

In one example, an electronic device includes a first substrate defining a first port and comprising an inner side and an outer side. A first electronic component includes a first microelectromechanical system (MEMS) device disposed over the first port and coupled to the inner side of the first substrate. A lid can be coupled to an outer side of the first substrate and can define a first volume between the lid and the first substrate. The first volume in can be fluid communication with the first port. A cavity substrate defines a cavity and can be coupled to the inner side of the first substrate with the first electronic component extending into the cavity. An inner side of a second substrate can be coupled to the cavity substrate. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a perspective view of an example electronic device.

FIGS. 1B and 1C show cross-sectional views of an example electronic device.

FIG. 1D shows a top view of an example cavity substrate.

FIGS. 2A to 2O show an example method for manufacturing an electronic device using cross-sectional and top views.

FIG. 3A shows a cross-sectional view of an example electronic device.

FIG. 3B shows a top view of an example cavity substrate.

FIG. 4 shows a top view of an example lid.

FIG. 5 shows a top view of an example lid.

FIG. 6 shows a top view of an example lid.

FIG. 7 shows a cross-sectional view of an example electronic device.

FIG. 8A shows a cross-sectional view of an example electronic device.

FIG. 8B shows a top view of an example cavity substrate.

FIG. 9A shows a cross-section view of an example cavity substrate.

FIG. 9B shows a top view of an example cavity substrate.

FIG. 10 shows a cross-sectional view of an example electronic device.

FIG. 11 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction. Descriptions and details of well-known features and techniques may be omitted to avoid unnecessarily obscuring the present disclosure. Elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to a mechanical or an electrical coupling.

### DESCRIPTION

An example electronic device comprises a first substrate defining a first port and comprising an inner side and an outer side. A first electronic component includes a first microelectromechanical system (MEMS) device disposed over the first port and coupled to the inner side of the first substrate. A lid can be coupled to an outer side of the first substrate and can define a first volume between the lid and the first substrate. The first volume in can be fluid communication with the first port. A cavity substrate defines a cavity and can be coupled to the inner side of the first substrate with the first electronic component extending into the cavity. An inner side of a second substrate can be coupled to the cavity substrate.

Another example electronic device can comprise a first substrate defining a first port. A first electronic component includes a first MEMS speaker disposed over the first port and coupled to an inner side of the first substrate. A cavity substrate defines a cavity and a side port. The cavity substrate can be coupled to the inner side of the first substrate with the first electronic component extending into the cavity. A second substrate can have an inner side of the second substrate coupled to the cavity substrate opposite the first substrate.

An example method of making an electronic device can include providing a first substrate defining a port. An electronic component can be coupled to an inner side of the first substrate. The electronic component includes a first MEMS device and can be disposed over the port. A cavity substrate is coupled to the inner side of the first substrate. The electronic component extends into a cavity. A second substrate can be coupled to the cavity substrate opposite the first substrate. A first lid can be coupled to an outer side of the first substrate. A first volume is defined between the first lid and the first substrate. The first volume is in fluid communication with the port.

Other examples are included in the present disclosure. Such examples may be found in the figures, in the claims, or in the description of the present disclosure.

Electronic devices and related methods of the present disclosure can improve audio performance and increase tuneability of microelectromechanical system (MEMS) speakers. A lid can be used on one side or multiple sides of a MEMS speaker device to define a volume in fluid communication with one or more speakers. Apertures in the lid can have predetermined shapes defining passages through the lid, and the apertures can be in fluid communication with the MEMS speaker. Some examples can include a diaphragm over the apertures. A side port can be used in some examples to fire sound from MEMS speakers laterally outside the electronic device. Some examples can include multiple MEMS speakers firing out of a shared side port. The inclusion of lids and side ports can improve tunability and control over the volume in communication with the MEMS speakers. The lids and side ports can also result in an increased volume of air being available to MEMS speakers in a same or smaller device footprint.

Various embodiments can include other types of MEMS devices. For example, some embodiments could incorporate a MEMS pump as the sole MEMS device included in an electronic device. In another example, a MEMS pump or a MEMS mixer can be included in an electronic device comprising multiple MEMS devices. Cavity substrates can have multiple side ports, top ports, bottom ports, or combinations thereof that can allow the electronic device to operate as a channel, into which other fluids can be added. The inner cavity can be designed to promote or reduce turbulence, depending on the desired effect. Some embodiments can include coatings with materials such as parylene to prevent reactions between the fluids and the device. In some examples, the MEMS element can be replaced with a piezo-membrane. While the present disclosure mostly describes MEMS speakers and similar devices below, it should be understood that other MEMS devices can be used in various embodiments.

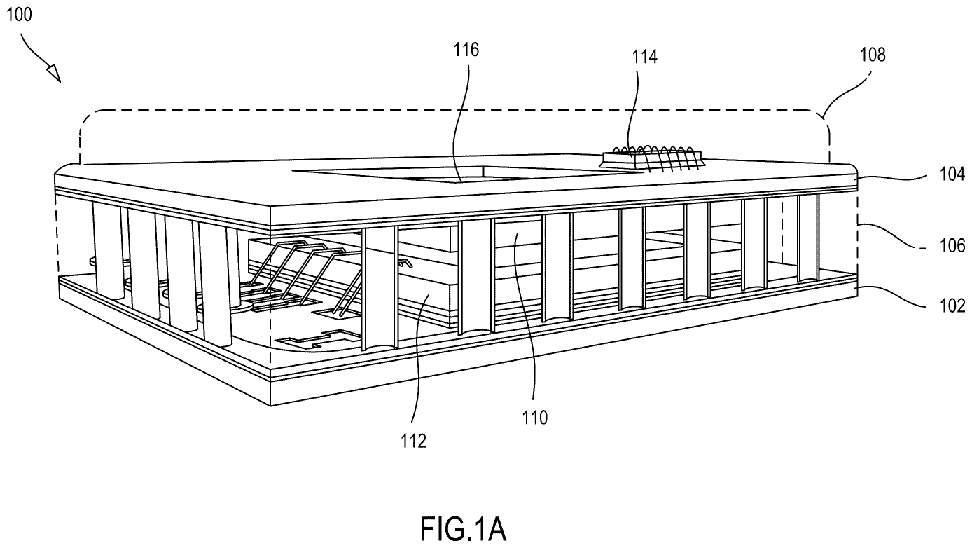

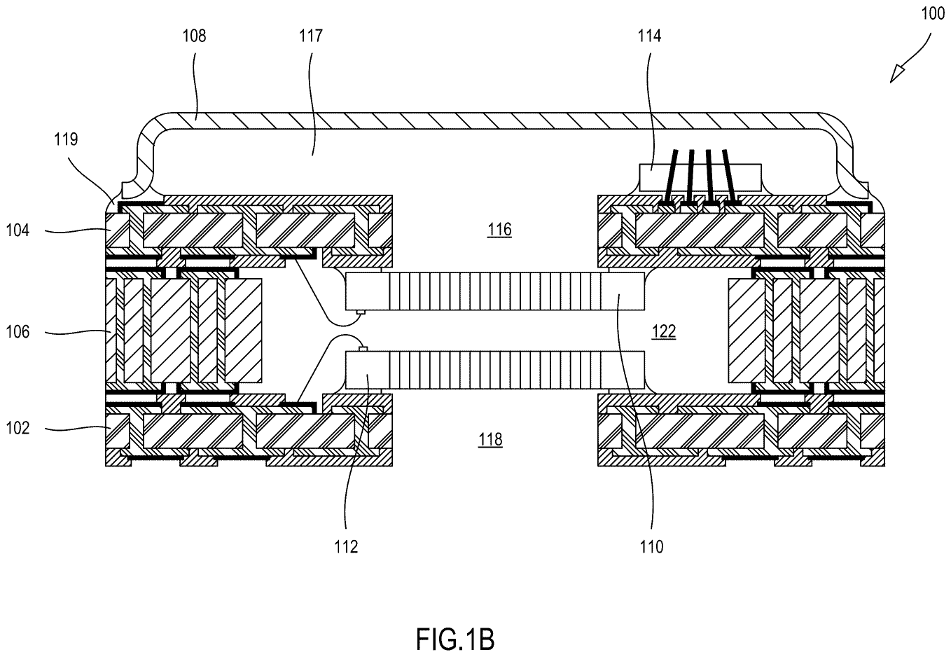

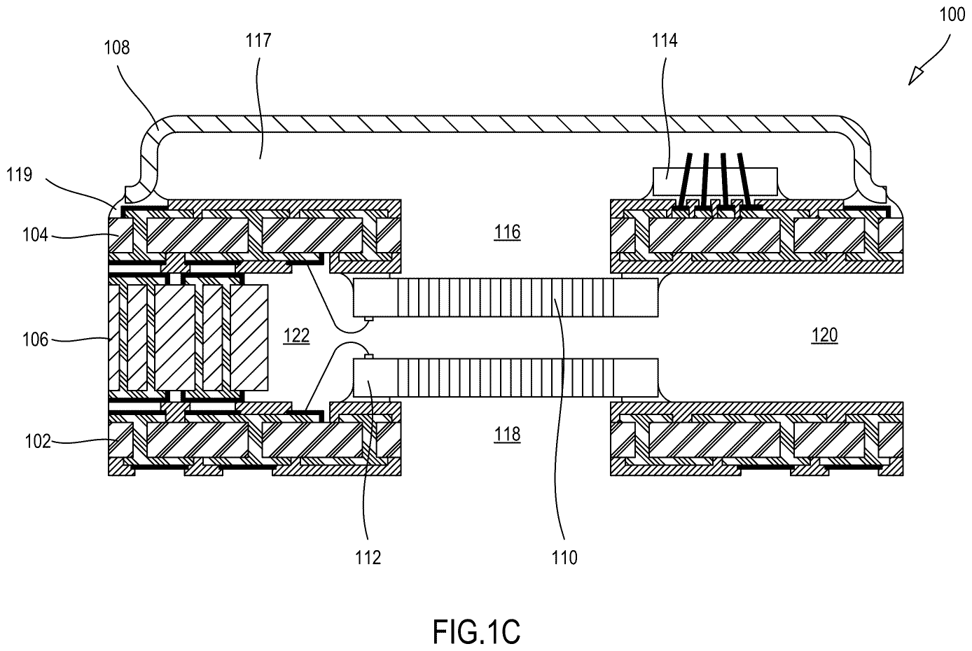

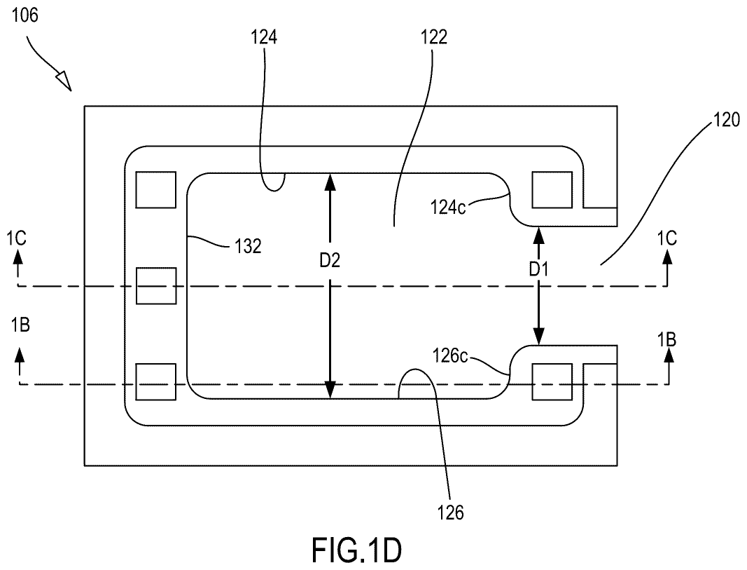

Referring now to FIGS. 1A, 1B, 1C, and 1D, a perspective view of an example electronic device 100, a cross-sectional view of electronic device 100 taken along line 1B-1B in FIG. 1D, a cross-sectional view of electronic device 100 taken along line 1C-1C in FIG. 1D, and a top view of a cavity substrate 106 of electronic device 100 are shown, respectively. In the example of FIGS. 1A-1D, electronic device 100 can comprise lower substrate 102, upper substrate 104, cavity substrate 106, lid 108, electronic component 110, electronic component 112, and electronic component 114. Lid 108 and the walls of cavity substrate 106 are illustrated as transparent in FIG. 1A to depict features of electronic device 100 that would otherwise be obstructed from view.

In some examples, electronic components 110 and 112 can comprise microelectromechanical systems (MEMS) die. For example, electronic components 110 and 112 can comprise MEMS speakers that produce sound in response to an electronic signal. Electronic component 114 can comprise an application-specific integrated circuit (ASIC) or other device included in electronic device 100. Substrate 104 can include or define port 116. Substrate 102 can include or define port 118. Cavity substrate 106 can include or define port 120 and die cavity 122. Die cavity 122 is fluidly connected to port 120. With specific reference to FIG. 1D, interior sidewalls 124 and 126 of cavity substrate 106 can define, at least a portion, of port 120 and of die cavity 122. Interior sidewall 124 can be oriented generally toward (i.e., facing) interior sidewall 126. Interior sidewall 132 can extend between and connect interior sidewall 124 and interior sidewall 126.

In some examples, a distance D1 between interior sidewall 124 and interior sidewall 126 in port 120 can be less than a distance D2 between interior sidewall 124 and interior sidewall 126 in die cavity 122. Port 120 can provide a fluid connection between die cavity 122 and the ambient environment. Interior sidewall 124 can include a connecting portion 124c proximate the interface between die cavity 122 and port 120. Interior sidewall 126 can include a connecting portion 126c proximate the interface between die cavity 122 and port 120. Connecting portions 124c, 126c can be generally parallel to interior sidewall 132.

Returning to FIGS. 1A-1C, lid 108 can define a volume 117 over substrate 104. Volume 117 can be in fluid communication with electronic component 110 through port 116. Electronic component 112 can be in fluid communication with the ambient environment through port 118. Electronic device 100 can expel sound through port 120. Electronic component 110 and electronic component 112 can each be vented to permit fluid (e.g., sound waves) to pass through electronic component 110 and electronic component 112, enabling access by both electronic components 110 and 112 to die cavity 122 and port 120. For example, the venting of electronic component 110 can provide fluid connection between port 116 and die cavity 122, and the venting of electronic component 112 can provide fluid connection between port 118 and die cavity 122.

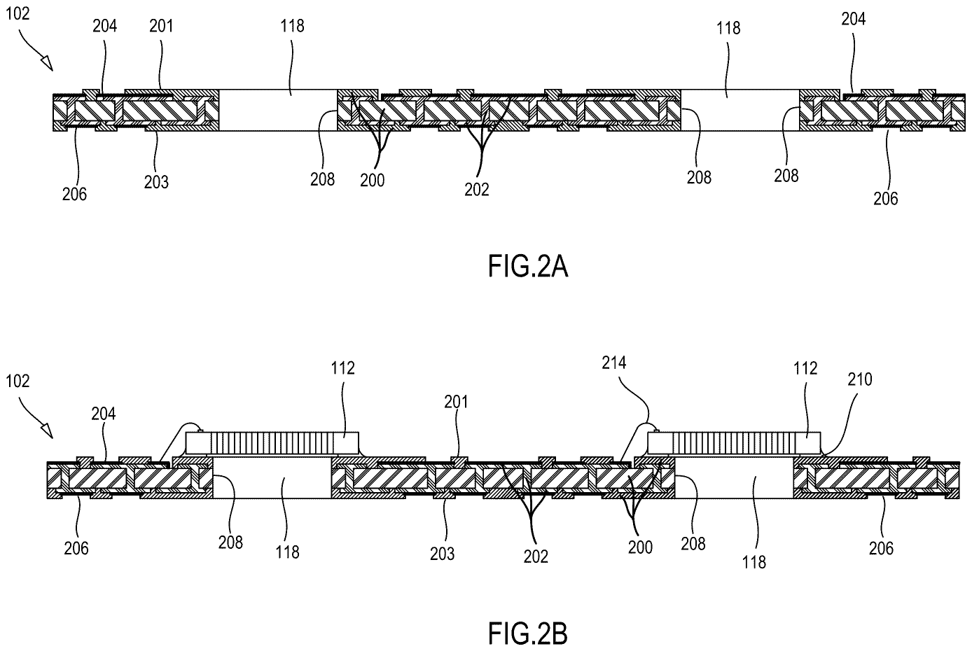

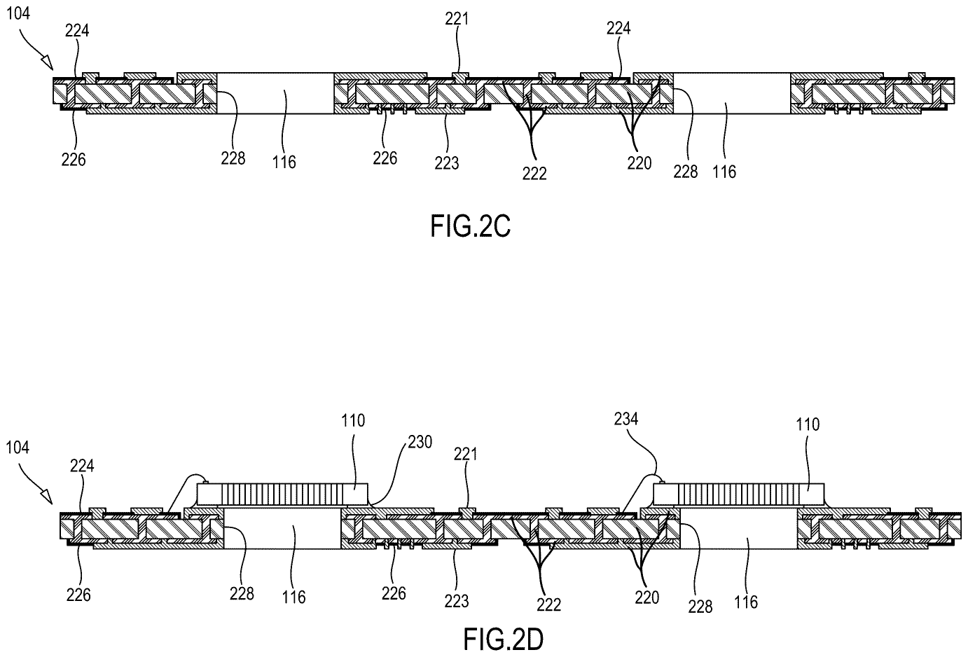

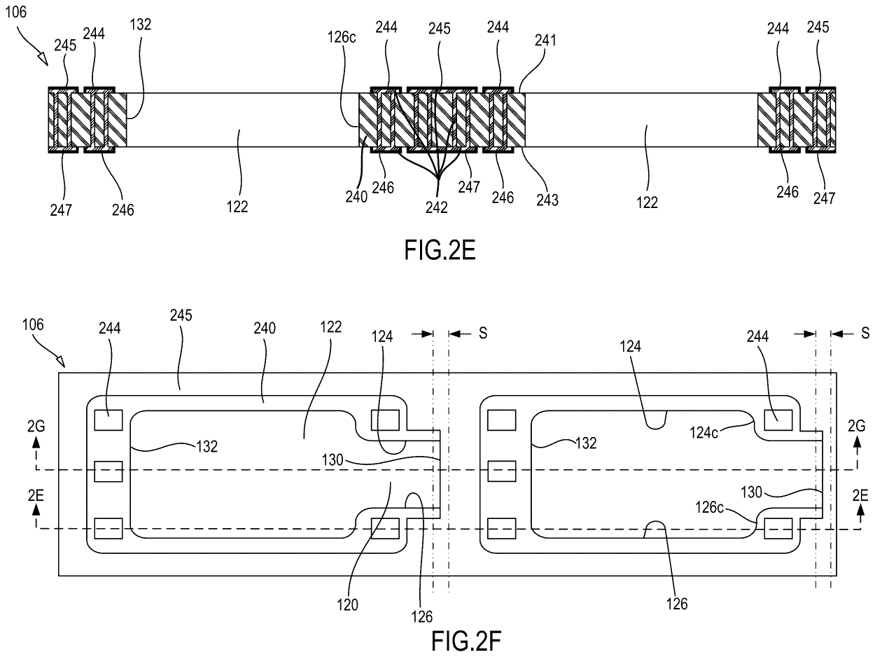

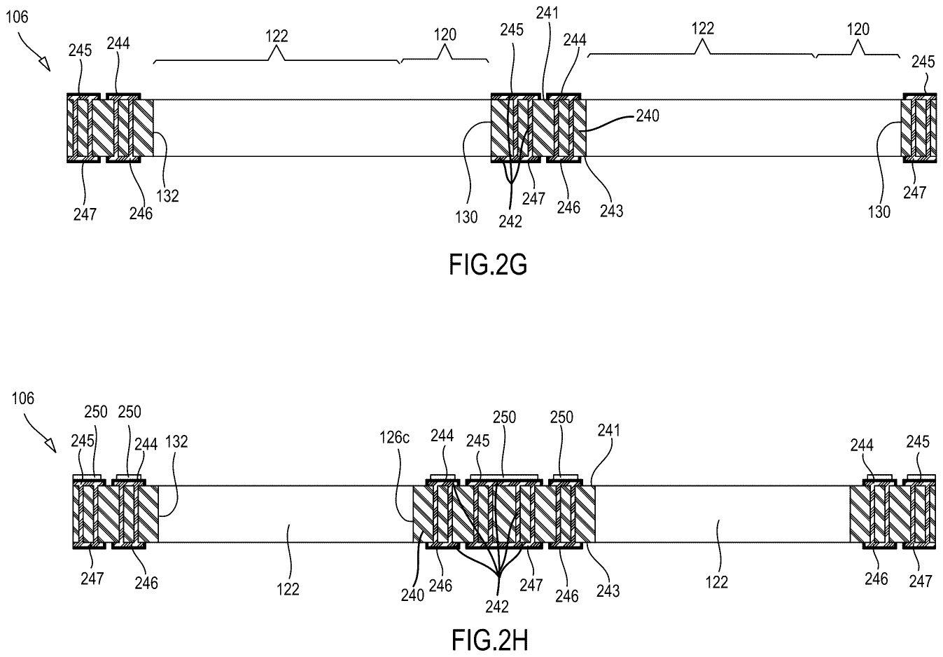

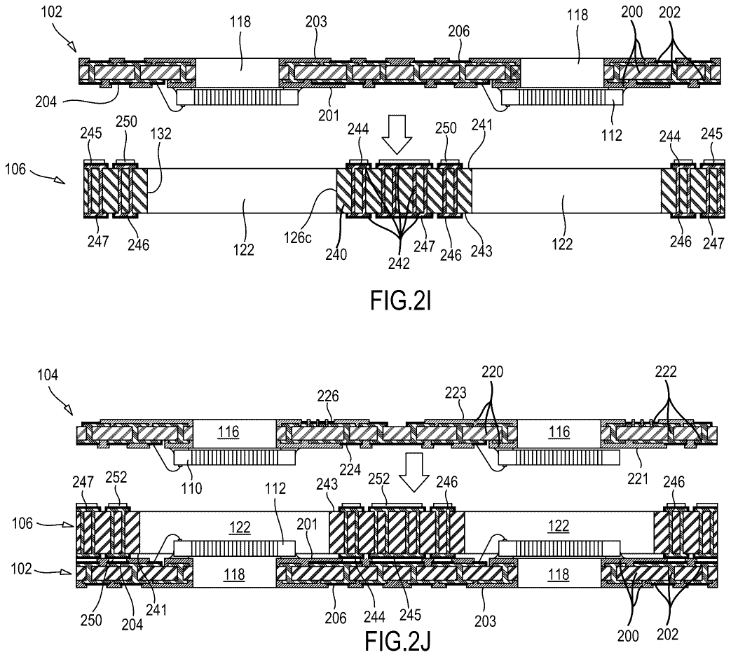

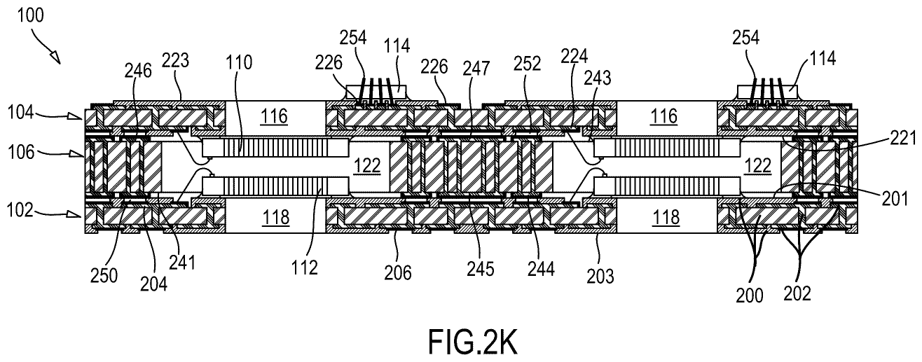

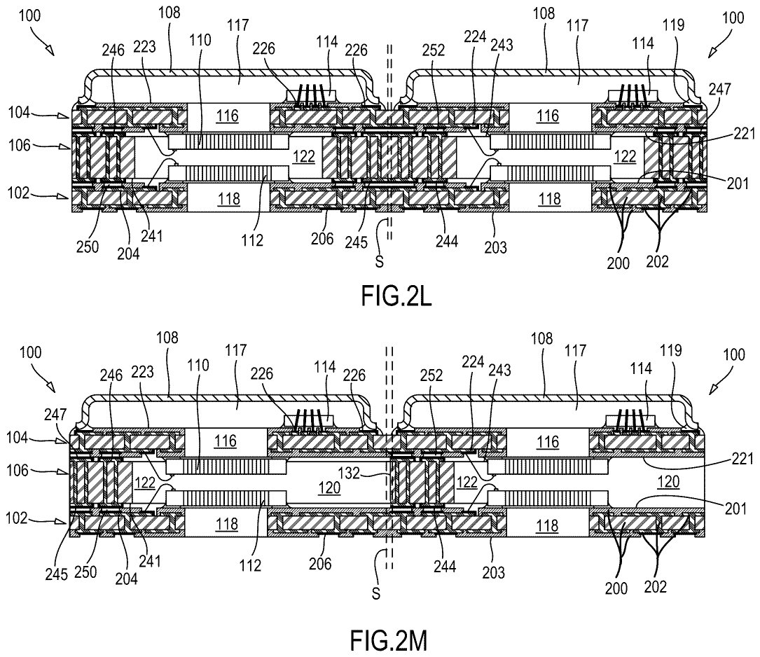

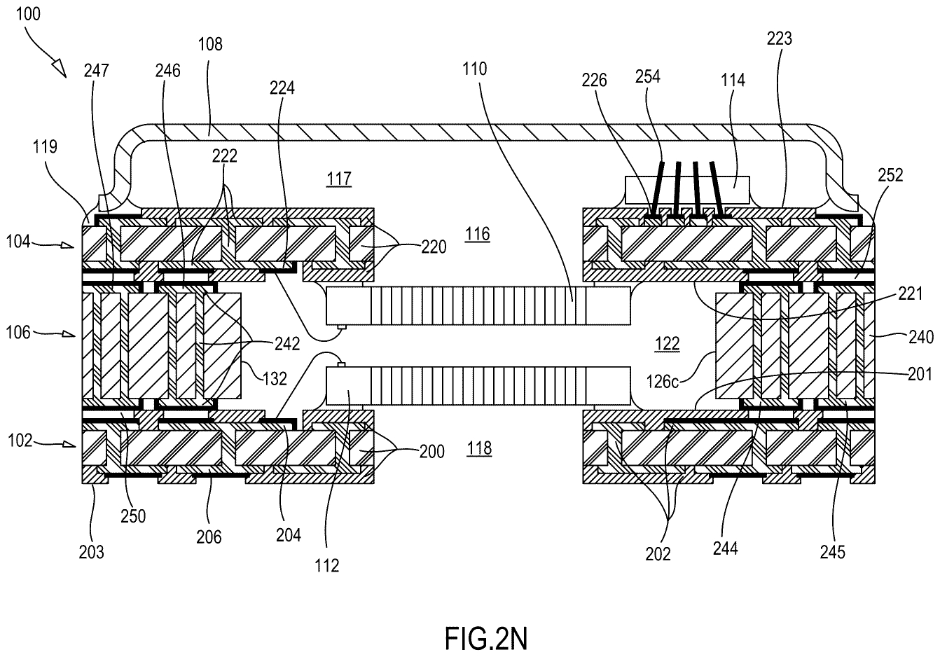

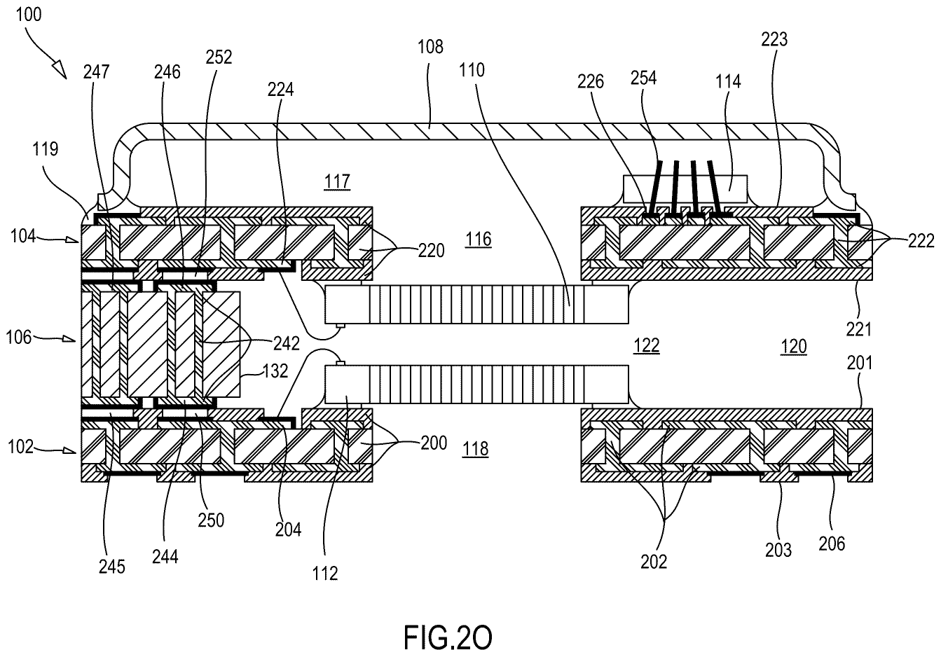

FIGS. 2A to 2O use cross-sectional views to illustrate an example method for manufacturing electronic device 100. Although FIGS. 2A to 2O are depicted in a particular order, methods steps depicted and described herein can be performed in any suitable order.

FIG. 2A shows a cross-sectional view of electronic device 100 at an early stage of manufacture. In the example shown in FIG. 2A, substrate 102 can be provided. Substrate 102 can include inner side 201 and outer side 203 opposite inner side 201. Substrate 102 can comprise dielectric structure 200 and conductive structure 202. Conductive structure 202 can include inner terminals 204 provided along inner side 201 of substrate 102, and outer terminals 206 provided along outer side 203 of substrate 102. Substrate 102 can include port 118. Port 118 can extend completely through substrate 102. For example, port 118 can extend from inner side 201 to outer side 203 of substrate 102. An inner wall 208 of substrate 102 can extend between inner side 201 and outer side 203 of substrate 102 and can define port 118.

In accordance with various examples, dielectric structure 200 can comprise or be referred to as one or more stacked dielectric layers. For instance, the one or more dielectric layers can comprise, one or more core layers, polymer layers, pre-preg layers, or solder mask layers provided on each other. One or more layers or elements of conductive structure 202 can be interleaved with elements or layers of dielectric structure 200. In some examples, dielectric structure 200 can comprise FR4 (copper foil/glass fiber fabric/copper foil laminate), bismaleimide triazine (BT), polyimide (PI), benzocyclobutene (BCB), polybenzoxazole (PBO), phenolic resin, Ajinomoto Buildup Film (ABF), mold compound, or glass. The thickness of individual layers of dielectric structure 200 can range from approximately 5.0 μm to approximately 1400 μm. As used herein with numeric values, the term “approximately” can mean +/−5%, +/−10%, +/−15%, +/−20%, or +/−25%.

In accordance with examples, individual layers of dielectric structure 200 (e.g., ABF or pre-preg layers) can be laminated to a core structure of dielectric structure 200 and/or to one another. In some examples, the core of dielectric structure 200 can have a thickness of between approximately 100 μm and approximately 1400 μm, between approximately 200 μm and 1250 μm, or between approximately 400 μm and 800 μm. In some examples, the core of dielectric structure 200 can have a thickness of approximately 200 μm, approximately 820 μm, or approximately 1250 μm. In some examples, the laminated layers of dielectric structure 200 can each have a thickness between approximately 5 μm and approximately 50 μm, between approximately 25 μm and approximately 40 μm, between approximately 25 μm and approximately 35 μm, of approximately 10 μm, of approximately 20 μm, of approximately 25 μm, or of approximately 33 μm.

In some examples, the outermost dielectric layer on each of inner side 201 and outer side 203 can comprise a solder resist material, which in some examples, can be different from the material of the core or the other dielectric layers between the core and the solder resist layer. In some examples, the solder resist layers can be provided by screen printing and can have a thickness of between approximately 10 μm and approximately 50 μm, between approximately 20 μm and approximately 40 μm, between approximately 20 μm and approximately 30 μm, of approximately 20 μm, or of approximately 22 μm. In some examples, the thickness of the solder resist layer can be less than the thickness of the other laminated dielectric layer(s). In some examples, the solder resist can be provided on the core, such that other laminated dielectric layers are omitted. The combined thickness of the layers of dielectric structure 200 can define the thickness of substrate 102. In some examples, a thickness of substrate 102 can range from approximately 20 μm to approximately 2000 μm or 100μm to approximately 1000 μm. Dielectric structure 200 can maintain the shape of substrate 102 and can structurally support conductive structure 202.

Conductive structure 202 can comprise or be referred to as one or more conductive layers defining signal distribution elements, traces, vias, pads, under bump metallization (UBM), redistribution layers (RDLs), conductive patterns, conductive paths, wiring patterns, or circuit patterns. Conductive structure 202 can be formed by electroless plating, electrolytic plating, sputtering, physical vapor deposition (PVD), chemical vapor deposition (CVD), or any other suitable deposition process. In some examples, conductive structure 202 can comprise one or more layers of copper (Cu), aluminum (Al), tin (Sn), titanium (Ti), titanium tungsten (TiW), vanadium (V), gold (Au), silver (Ag), nickel (Ni), palladium (Pd), or combinations or alloys thereof. The thickness of conductive structure 202 can be from approximately 5 μm to approximately 50 μm, 10 μm to approximately 30 μm, 15 μm to approximately 25 μm, or 18 μm to approximately 20 μm. The thickness of conductive structure 202 can refer to individual layers of conductive structure 202. In some examples, conductive structure 202 can have a trace width and trace spacing (width/spacing) of between approximately 5 μm/5 μm and approximately 50 μm/50 μm, between approximately 8 μm/8 μm and approximately 40 μm/40 μm, between approximately 9μm/12 μm and approximately 25 μm/25 μm, or between approximately 9μm/12 μm and approximately 20 μm/20μm. Trace width is the width of individual traces of conductive structure 202 and trace spacing is the distance between adjacent traces of conductive structure 202. Conductive structure 202 provides electrical signal paths (e.g., vertical paths and horizontal paths) through dielectric structure 200.

Conductive structure 202 can comprise inner terminals 204 provided along inner side 201 of substrate 102, and outer terminals 206 provided along outer side 203 of substrate 102. In some examples, inner terminals 204 and outer terminals 206 can comprise or be referred to as pads, lands, or UBM. Layers and elements of conductive structure 202 can electrically couple inner terminals 204 with outer terminals 206.

Substrate 102 can comprise a core or can be coreless. In some examples, substrate 102 can comprise or be referred to as a pre-formed or laminate substrate. It is contemplated and understood that one or more layers or elements of conductive structure 202 can be interleaved with one or more layers or elements of dielectric structure 200, and that dielectric structure 200 and conductive structure 202 can each include any number of layers in substrate 102.

In accordance with various examples, pre-formed substrates can be manufactured prior to attachment to an electronic device and can comprise dielectric layers between respective conductive layers. The conductive layers can comprise copper and can be formed using an electroplating process. The dielectric layers can be thicker non-photo-definable layers and can be attached as a pre-formed film rather than as a liquid and can include a core layer having resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF.

The pre-formed substrate can include a permanent core structure or carrier such as, for example, a glass or dielectric material comprising BT or FR4, and dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process.

FIG. 2B shows a cross-sectional view of electronic device 100 at a later stage of manufacture. In the example of FIG. 2B, electronic component 112 can be provided over substrate 102. Electronic component 112 can comprise or be referred to as a die, a chip, a package, or a device. In some examples, electronic component 112 comprises a MEMS speaker. The thickness of electronic component 112 can range from approximately 10 μm to approximately 3,000 μm.

In various examples, an adhesive 210 can be disposed on inner side 201 of substrate 102 around a perimeter of port 118. Adhesive 210 can couple electronic component 112 to substrate 102. Electronic component 112 can be disposed over port 118. Electronic component 112 can cover port 118, and the volume between the perimeter of port 118 and electronic component 112 can be sealed or substantially sealed by adhesive 210. In some examples, sealing can be partial to provide a vent. Electronic component 112 can be vented (e.g., include vias, openings, channels, etc.) to allow the passage of fluid (e.g., sound waves) through electronic component 112. In accordance with various examples, one or more component interconnect(s) 214 can electrically couple electronic component 112 to inner terminals 204 of substrate 102. While component interconnects 214 are shown as wire bonds coupling a top or distal side of electronic component 112 to substrate 102, it is contemplated and understood that in some examples, component interconnects 214 could comprise bumps, pillars, or posts, and could be coupled in a flip chip configuration between a bottom or proximate side of electronic component 112 and substrate 102.

FIG. 2C shows a cross-sectional view of electronic device 100 at a later stage of manufacture. In the example of FIG. 2C, substrate 104 can be provided. Substrate 104 can include inner side 221 and outer side 223 opposite inner side 221. Substrate 104 can comprise dielectric structure 220 and conductive structure 222. Conductive structure 222 can include inner terminals 224 provided along inner side 221 of substrate 104, and outer terminals 226 provided along outer side 223 of substrate 104. Substrate 104 can include port 116. Port 116 can extend completely through substrate 104. For example, port 116 can extend from inner side 221 to outer side 223 of substrate 104. An inner wall 228 of substrate 104 can extend between inner side 221 and outer side 223 of substrate 104 and can define port 116. In some examples, a thickness of substrate 104 can range from approximately 20 μm to approximately 2000 μm or 100 μm to approximately 1000 μm. The elements, features, materials, or manufacturing methods of substrate 104, dielectric structure 220, conductive structure 222, inner terminals 224, outer terminals 226, and port 116 can be similar to or the same as elements, features, materials, or manufacturing methods of substrate 102, dielectric structure 200, conductive structure 202, inner terminals 204, outer terminals 206, and port 118, respectively.

FIG. 2D shows a cross-sectional view of electronic device 100 at a later stage of manufacture. In the example of FIG. 2D, electronic component 110 can be provided over substrate 104. Electronic component 110 can comprise or be referred to as a die, a chip, a package, or a device. In some examples, electronic component 110 comprises a MEMS speaker. A thickness of electronic component 110 can range from approximately 10 μm to approximately 3,000 μm.

In various examples, an adhesive 230 can be disposed on inner side 221 of substrate 104 around a perimeter of port 116. Adhesive 230 can couple electronic component 110 to substrate 104. Electronic component 110 can be disposed over port 116. Electronic component 110 can cover port 116, and the volume between the perimeter of port 116 and electronic component 110 can be sealed or substantially sealed by adhesive 230. Electronic component 110 can be vented to allow the passage of fluid (e.g., sound waves) through electronic component 110. One or more component interconnect(s) 234 can electrically couple electronic component 110 to inner terminals 224 of substrate 104. While component interconnects 234 are shown as wire bonds coupling a top or distal side of electronic component 110 to substrate 104, it is contemplated and understood that in some examples, component interconnects 234 could comprise bumps, pillars, or posts, and could be coupled in a flip chip configuration between a bottom or proximate side of electronic component 110 and substrate 104.

Referring now to FIGS. 2E, 2F, and 2G, cross-sectional views (FIGS. 2E and 2G) and a top-down view (FIG. 2F) of electronic device 100 are shown at a later stage of manufacture. In the example of FIGS. 2E, 2F and 2G, cavity substrate 106 can be provided. FIG. 2E shows a cross-sectional view of cavity substrate 106 taken along line 2E-2E in FIG. 2F, in accordance with various examples. FIG. 2F shows a top-down view of cavity substrate 106, in accordance with various examples. FIG. 2G shows a cross-sectional view of cavity substrate 106 taken along line 2G-2G in FIG. 2F, in accordance with various examples. Cavity substrate 106 can define die cavity 122 suitable for receiving electronic components 110 and 112, for example. Cavity substrate 106 can further define side-firing port 120 between interior sidewall 124 and interior sidewall 126. Port 120 can terminate at an inner wall 130 of cavity substrate 106. Inner wall 130 can be oriented toward interior sidewall 132. Interior sidewall 132 and inner wall 130 can each extend between interior sidewall 124 and interior sidewall 126. In some examples, interior sidewall 124 and interior sidewall 126 can each include a connecting portion 124c, 126c, respectively, proximate the interface between die cavity 122 and port 120. Connecting portions 124c, 126c can be generally parallel to interior sidewall 132 and/or inner wall 130.

In accordance with various examples, port 120 can be opened in response to singulation. As subsequently described, adjacent cavity substrates 106 can be singulated by cutting through saw street S. During singulation, inner wall 130 can be removed, thereby opening port 120 and fluidly connecting die cavity 122 with an environment external to cavity substrate 106 and electronic device 100.

In accordance with various examples, cavity substrate 106 can include side 241 and side 243 opposite side 241. Die cavity 122 can extend completely through cavity substrate 106, such that die cavity 122 extends from side 241 to side 243 of cavity substrate 106. In some examples, port 120 can extend completely through cavity substrate 106. For example, port 120 can extend from side 241 to side 243 of cavity substrate 106. Die cavity 122 and/or port 120 can be formed by milling, stamping, drilling, or using other material removal or aperture forming techniques.

Cavity substrate 106 comprises dielectric structure 240 and conductive structure 242. Conductive structure 242 can include conductor 245 and terminals 244 provided along side 241 of cavity substrate 106, and conductor 247 and terminals 246 provided along side 243 of cavity substrate 106. In some examples, conductor 245 and/or conductor 247 can each comprise a continuous conductive material (e.g., Cu, Ni, Ag, Au, etc.) disposed around a perimeter of cavity substrate 106 and between adjacent cavity substrates 106 prior to singulation (e.g., a portion of conductors 245 and 247 can be located in saw street S). Port 120 can also extend into saw street s (i.e., saw street S can vertically overlap port 120). Singulation can be used to open port 120. Terminals 244 can be disposed over dielectric structure 240 along side 241 of cavity substrate 106. Terminals 244 can be adjacent die cavity 122. For example, terminals 244 can be between conductor 245 and die cavity 122. Terminals 246 can be disposed over dielectric structure 240 along side 243 of cavity substrate 106. Terminals 246 can be adjacent die cavity 122. For example, terminals 246 can be between conductor 247 and die cavity 122.

Dielectric structure 240 can comprise or be referred to as one or more stacked dielectric layers. For instance, the one or more dielectric layers can comprise, one or more core layers, polymer layers, pre-preg layers, or solder mask layers stacked on each other. The elements, features, materials, or manufacturing methods of cavity substrate 106, dielectric structure 240, and conductive structure 242 can be similar to or the same as elements, features, materials, or manufacturing methods of substrate 102, dielectric structure 200, and conductive structure 202, respectively. While dielectric structure 240 is shown generally including one core layer, it is contemplated and understood that, in some examples, dielectric structure 240 could include additional dielectric layers located, at least partially, over conductor 245, terminals 244, conductor 247, or terminals 246. It is further contemplated and understood that dielectric structure 240 and conductive structure 242 of cavity substrate 106 can include any number (two, four, etc.) of additional interleaved dielectric and conductive layers. In some examples, a thickness of cavity substrate 106 can range from approximately 50 μm to approximately 2,000 μm.

FIG. 2H shows a cross-sectional view of electronic device 100 at a later stage of manufacture. FIG. 2H through FIG. 2M show the cross-sectional view taken along line 2E-2E in FIG. 2F. In the example of FIG. 2H, internal interconnects 250 can be provided over terminals 244 and conductor 245. Internal interconnects 250 can be coupled to terminals 244 and conductor 245. In some examples, internal interconnects 250 can comprise tin (Sn), silver (Ag), lead (Pb), copper (Cu), Sn—Pb, Sn₃₇—Pb, Sn₉₅—Pb, Sn—Pb—Ag, Sn—Pb—Bi, Sn—Cu, Sn—Ag, Sn—Au, Sn—Bi, Sn—Ag—Cu, Sn—Ag—Bi, Sn—Zn, or Sn'Zn—Bi. In some examples, internal interconnects 250 can comprise a silver epoxy. In some examples, after temporarily placing a conductive material containing solder on terminals 244 and conductor 245, through a ball drop method, screen or stencil printing, preform placement, or other techniques, internal interconnects 250 can be completed through a reflow process. Internal interconnects 250 can be referred to as eutectic material, flowable material, solder paste, conductive adhesive, or fusible material.

FIG. 2I shows electronic device 100 at a later stage of manufacture. In the example of FIG. 2G, substrate 102 is coupled to cavity substrate 106. Inner terminals 204 of substrate 102 can be aligned over internal interconnects 250 of cavity substrate 106. Internal interconnects 250 can couple terminals 244 and conductor 245 of cavity substrate 106 to inner terminals 204 of substrate 102. Die cavity 122 can be vertically aligned with electronic component 112. Electronic component 112 can extend into die cavity 122 of cavity substrate 106, after substrate 102 is coupled to cavity substrate 106.

FIG. 2J shows electronic device 100 at a later stage of manufacture. In the example of FIG. 2J, the workpiece including cavity substrate 106 and substrate 102 can be flipped, with terminals 246 and conductor 247 oriented upward. Internal interconnects 252 can be provided over terminals 246 and conductor 247. Internal interconnects 252 can be coupled to terminals 246 and conductor 247. Techniques and materials used to provide internal interconnects 252 can be similar to or the same as techniques and materials used to provide internal interconnects 250, as previously described.

As further shown in FIG. 2J, substrate 104 can be coupled to side 243 of cavity substrate 106. For example, substrate 104 can be coupled to cavity substrate 106 opposite substrate 102. Inner terminals 224 of substrate 104 can be aligned over internal interconnects 252 of cavity substrate 106. Internal interconnects 252 can couple terminals 246 and conductor 247 of cavity substrate 106 to inner terminals 224 of substrate 104.

In various examples, die cavity 122 can be vertically aligned with electronic component 110. Electronic component 110 can extend into die cavity 122 of cavity substrate 106, after substrate 104 is coupled to cavity substrate 106. Electronic component 110 can be over and spaced apart from electronic component 112. Electronic component 110 and electronic component 112 can both be in die cavity 122 defined by cavity substrate 106.

FIG. 2K shows electronic device 100 at a later stage of manufacture. In the example of FIG. 2K, electronic component 114 can be disposed on outer side 223 of substrate 104. Electronic component 114 is shown as added during the example stage of manufacture depicted in FIG. 2K. In various examples including passives, the passives can be assembled along with electronic component 114 or during other stages of manufacture. One or more component interconnect(s) 254 can electrically couple electronic component 114 to outer terminals 226 of substrate 104. While component interconnects 254 are shown as wire bonds coupling a top or distal side of electronic component 114 to substrate 104, it is contemplated and understood that in some examples, component interconnects 254 could comprise bumps, pillars, or posts, and could be coupled in a flip chip configuration between a bottom or proximate side of electronic component 114 and substrate 104.

FIGS. 2L and 2M show electronic device 100 at a later stage of manufacture. FIG. 2L shows a cross-sectional view of electronic device 100 taken along line 2E-2E in FIG. 2F. FIG. 2M shows a cross-sectional view of electronic device 100 taken along line 2G-2G in FIG. 2F. In the example of FIGS. 2L and 2M, lid 108 can be provided over substrate 104. Lid attach material 119 can be provided over outer side 223 of substrate 104. Lid attach material 119 can comprise an adhesive, solder, paste, preform, film, epoxy or other material suitable for coupling lid 108 to substrate 104. Lid attach material 119 can couple lid 108 to substrate 104. In some examples, lid 108 can comprise a metal lid having a u-shaped cross section. In some examples relating to microfluidics, lid 108 can comprise glass or plastic and can include a spout to mate with tubing. Lid 108 can comprise a metal or alloy lid. Lid 108 can define volume 117 between substrate 104 and lid 108. In some examples, volume 117 can contain from 0.5 cubic centimeters (cc) to 5 cc. Volume 117 can be in fluid communication with port 116, die cavity 122, port 118, and port 120. In some examples, lid 108 can comprise a side-firing port.

In accordance with various embodiments, substrates 102, 104, and 106 can be configured with a saw street S located between adjacent electronic devices 100. Saw street S can overlap or extend through port 120.

FIGS. 2N and 2O show a cross-sectional view of electronic device 100 after singulation. FIG. 2N shows a cross-sectional view of electronic device 100 taken along line 1B-1B in FIG. 1D. FIG. 2O shows a cross-sectional view of electronic device 100 taken along line 1C-1C in FIG. 1D. In the example shown in FIGS. 2N and 2O, a sawing or singulation process can be performed along saw street S (of FIGS. 2L and 2M). In some examples, individual electronic device 100 can be separated by a sawing tool, such as a diamond blade wheel or laser beam. In some examples, sawing can be performed by a sawing tool through substrate 102, through cavity substrate 106, and through substrate 104, or in the reverse order. Accordingly, the lateral sides of substrate 102, cavity substrate 106, and substrate 104 can be coplanar after singulation. Singulation can open port 120. For example, after singulation port 120 can fluidly connect die cavity 122 to the ambient environment external to electronic device 100.

Electronic device 100 provides a volume 117 for electronic components 110 and 112 to use in generating sound. The size of volume 117 can be tunable by selecting the depth of lid 108. Sound generated by electronic component 110 and electronic component 112 can resonate in volume 117. Electronic device 100 can comprise a single-package assembly including two electronic components 110 and 112 (e.g., MEMS speaker packages). Including two MEMS devices in a single package can reduce the volume occupied by the MEMS devices and conserve space for batteries, other electronics, or reduced external device dimensions. Although electronic components 110 and 112 are depicted on the inner sides 221, 201 of substrates 104 and 102, respectively, the electronic components (e.g., MEMS die) can also be disposed on outer side 203 and/or outer side 223, in various examples. The flexibility of MEMS die positioning on the inner or outer sides of electronic device 100 can improve performance available by selectively tuning the volumes of volume 117 and die cavity 122, and by selectively tuning volumes, sizes, and locations of port 116, port 118, and port 120.

A volume of port 120 can be defined by controlling a distance between inner sides 221, 201 of substrates 104 and 102, respectively. In some examples, the volume of port 120 can be controlled by selecting a thickness of cavity substrate 106. In some examples, the volume of port 120 can be controlled to achieve a desired sound characteristic or sound exiting port 120.

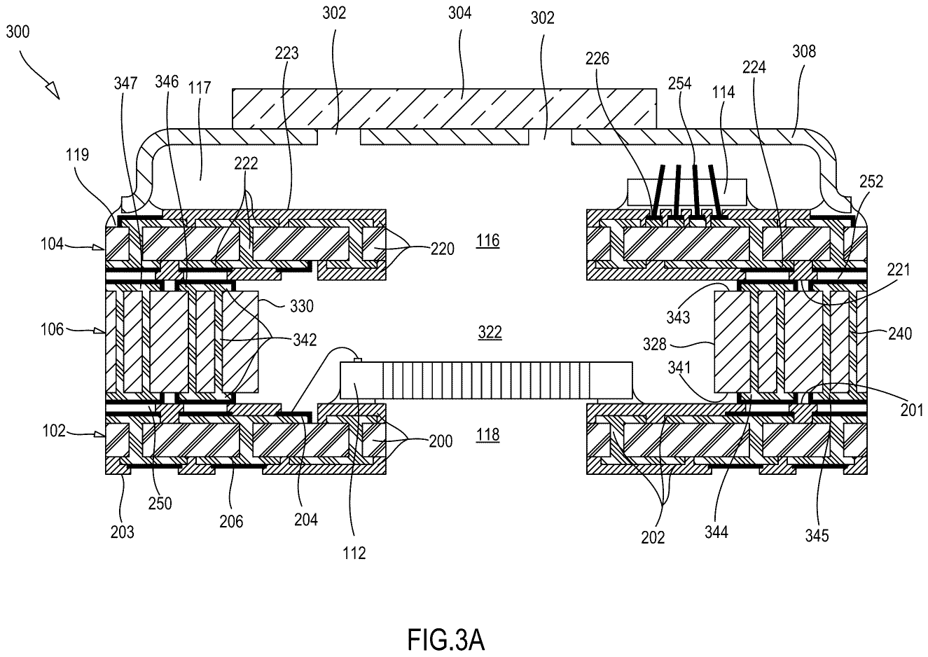

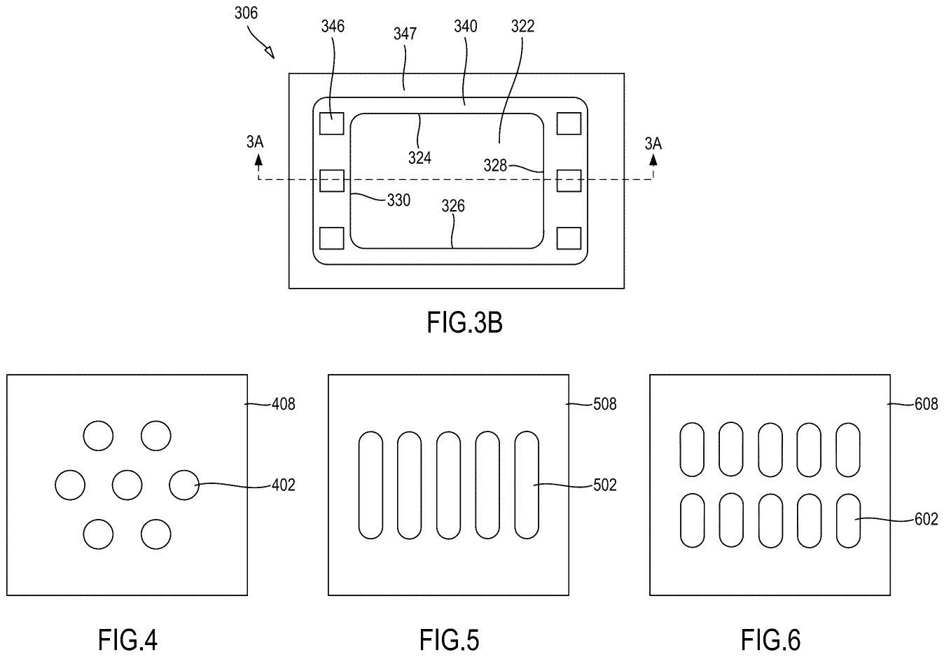

Referring now to FIG. 3A, an electronic device 300 is shown, in accordance with various examples. Electronic device 300 can comprise elements similar to or the same as electronic device 100. In some examples, electronic device 300 can include cavity substrate 306. Cavity substrate 306 can be similar to cavity substrate 106, but devoid of port 120. For example, cavity substrate 306 can create a fluid seal between inner side 201 of substrate 102 and inner side 221 of substrate 104.

FIG. 3B shows a top-down view of cavity substrate 306. Cavity substrate 306 can include interior walls 324, 326, 328, and 330. Interior wall 324 can be oriented toward interior wall 326. Interior wall 328 can be oriented toward interior wall 330. Interior walls 328 and 330 can extend between interior wall 324 and interior wall 326. Interior walls 324, 326, 328, and 330 can form a continuous wall or perimeter around (or defining) die cavity 322. FIG. 3A shows a cross-sectional view taken along line 3A-3A in FIG. 3B

With combined reference to FIGS. 3A and 3B, cavity substrate 306 comprises dielectric structure 340 and conductive structure 342. Conductive structure 342 can include conductor 345 and terminals 344 provided along side 341 of cavity substrate 306. Conductive structure 342 can further include conductor 347 and terminals 346 provided along side 343 of cavity substrate 306. The elements, features, materials, or manufacturing methods of cavity substrate 306, dielectric structure 340 and conductive structure 342 can be similar to or the same as elements, features, materials, or manufacturing methods of cavity substrate 106, dielectric structure 240 and conductive structure 242, respectively.

Internal interconnects 250 can couple inner terminals 204 of substrate 102 to conductor 345 and terminals 344 of cavity substrate 306. Internal interconnects 252 can couple inner terminals 224 of substrate 104 to conductor 347 and terminals 346 of cavity substrate 306.

In various examples, electronic device 300 can further include apertures 302 (also referred to as ports or openings) extending through lid 308. Apertures 302 can be in fluid communication with volume 117, port 116, die cavity 322, and port 118. In the example of FIG. 3, electronic device 300 comprises a single electronic component 112 coupled to inner side 201 of substrate 102. Diaphragm 304 can be coupled to lid 308 over apertures 302. In some examples, diaphragm 304 can comprise a textile, fibers, film, or other suitable materials. Diaphragm 304 can cover apertures 302 to inhibit ingress of contaminants. Diaphragm 304 can also contribute to characteristics of sound exiting port 118. Apertures 302 can have circular, elongated, slotted, oval, or other geometries.

With brief reference to FIG. 4, an example lid 408 is shown in top view. Lid 408 can include elements similar to or the same as lid 108 in various examples. In the example of FIG. 4, lid 408 includes circular apertures 402. Circular apertures 402 can extend completely through lid 408. Circular apertures 402 can be arranged in rows, columns, arrays, grids, or other arrangements suitable for enabling fluid communication across lid 408. Lid 408 can include a diaphragm over circular apertures 402 in various examples. Circular apertures 402 can inhibit ingress and egress of debris of particles that might otherwise damage the actuator or MEMS structure of electronic components 110 or 112 (of FIG. 1B). In some examples, circular apertures 402 can be defined through a protective metal plate or lid disposed over port 118 (of FIG. 1B) to prevent ingress and egress of debris or particles. In some examples, the patterns of circular apertures 402 can be created in lid 108 or other substrates through the full thickness of the lid. In some examples, the patterns of circular apertures 402 can be created by removing a dielectric (e.g., releasing Cu foil) and patterning free-standing foil.

With brief reference to FIG. 5, an example lid 508 is shown in top view. Lid 508 can include elements similar to or the same as lid 408 in various examples. In the example of FIG. 5, lid 508 includes elongated apertures 502. Elongated apertures 502 can extend completely through lid 508. Elongated apertures 502 can be arranged in rows, columns, arrays, grids, or other arrangements suitable for enabling fluid communication across lid 508. Lid 508 can include a diaphragm over elongated apertures 502 in various examples. Elongated apertures 502 can inhibit ingress and egress of debris of particles that might otherwise damage the actuator or MEMS structure of electronic components 110 or 112 (of FIG. 1B). In some examples, elongated apertures 502 can be defined through a protective metal plate disposed over port 118 (of FIG. 1B) to prevent ingress and egress of debris or particles. For example, elongated apertures 502 can be defined through a protective metal plate coupled to outer side 203 of substrate 102 (of FIG. 1B).

With brief reference to FIG. 6, another example lid 608 is shown in top view. Lid 608 can include elements similar to or the same as lid 508 in various examples. In the example of FIG. 6, lid 608 includes slotted apertures 602. Slotted apertures 602 can extend completely through lid 608. Slotted apertures 602 can be arranged in rows, columns, arrays, grids, or other arrangements suitable for enabling fluid communication across lid 608. Lid 608 can include a diaphragm over slotted apertures 602 in various examples. Slotted apertures 602 can inhibit ingress and egress of debris of particles that might otherwise damage the actuator or MEMS structure of electronic components 110 or 112 (of FIG. 1B). In some examples, slotted apertures 602 can be defined through a protective metal plate disposed over port 118 (of FIG. 1B) to prevent ingress and egress of debris or particles. For example, slotted apertures 602 can be defined through a protective metal plate coupled to outer side 203 of substrate 102 (of FIG. 1B).

The various lid and aperture configurations disclosed herein can be used interchangeably in various examples. Aperture sizes, locations, shapes, and surface areas (e.g., as viewed from above in FIGS. 4-6) can be selectively tuned to produce a desired output sound from electronic devices of the present disclosure. In some examples, the aperture size can range from approximately 20 μm to approximately 2,000 μm. Diaphragm materials and characteristics can further be selected and coupled to lids or plates covering the selectively tuned ports to generate a desired output sound.

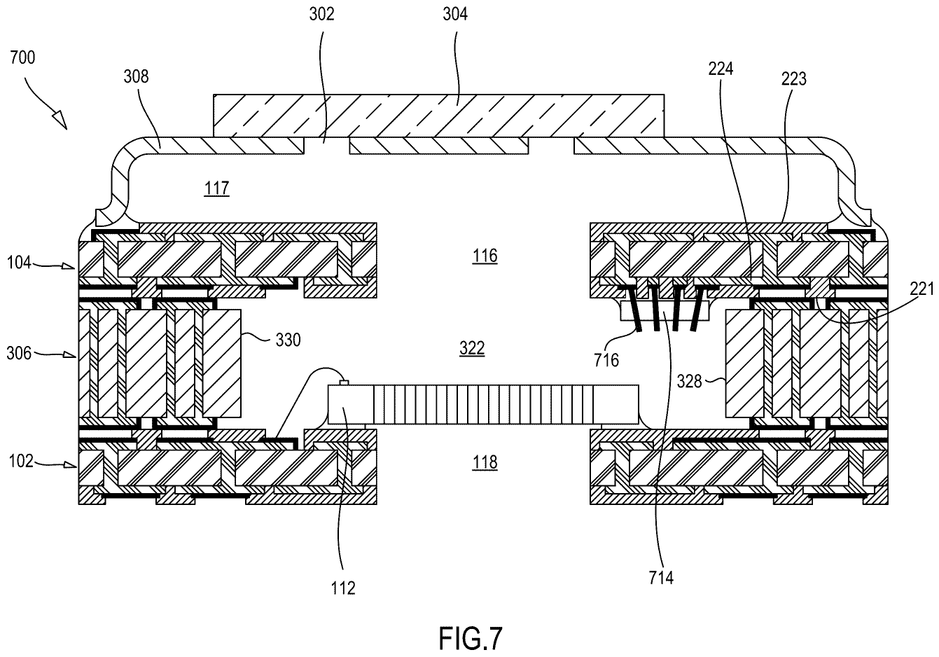

With reference to FIG. 7, an example electronic device 700 is shown, in accordance with various examples. Electronic device 700 can include elements similar to or the same as those described above for electronic device 300 (of FIG. 3) or other electronic devices described herein. Electronic device 700 can include volume 117 omitting or devoid of electronic component 114 (of FIG. 3). Volume 117 can be defined by outer side 223 of substrate 104 and an inner side of lid 308, and can be substantially obstruction free. Electronic component 714 can be disposed on inner side 221 of substrate 104 and can extend into die cavity 322. One or more component interconnect(s) 716 can electrically couple electronic component 714 to inner terminals 224 of substrate 104. While component interconnects 716 are shown as wire bonds coupling a bottom or distal side of electronic component 714 to substrate 104, it is contemplated and understood that in some examples, component interconnects 716 could comprise bumps, pillars, or posts, and could be coupled in a flip chip configuration between a top or proximate side of electronic component 714 and substrate 104. Electronic component 714 of FIG. 7 can be similar to or the same as electronic component 114 but located in die cavity 322. In some examples, a membrane or diaphragm similar to diaphragm 304 can cover port 118.

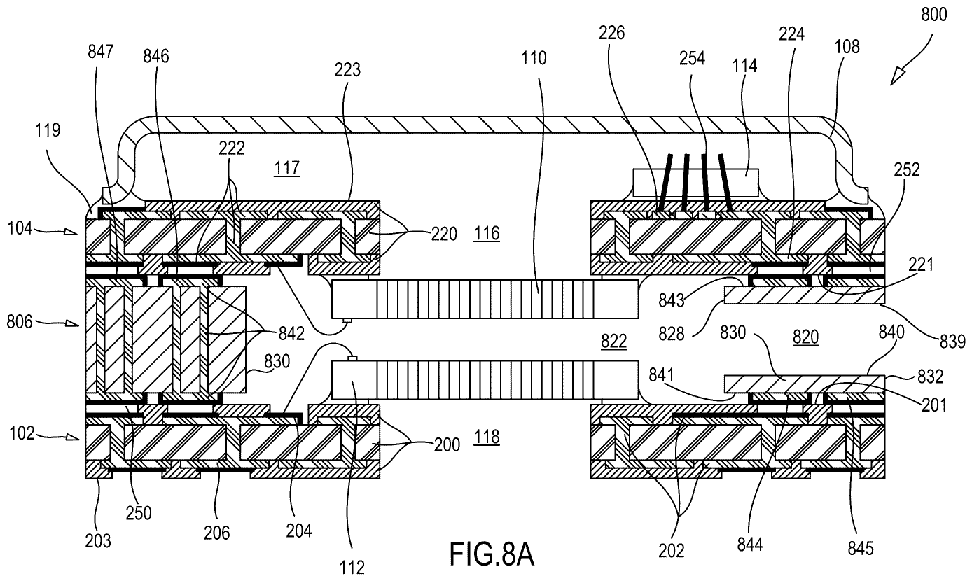

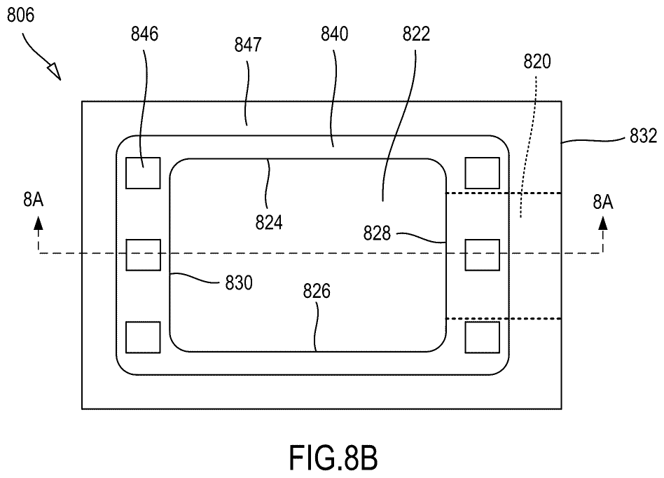

Referring now to FIG. 8A, an electronic device 800 is shown, in accordance with various examples. Electronic device 800 can comprise elements similar to or the same as electronic device 100. In some examples, electronic device 800 can include cavity substrate 806. Cavity substrate 806 can be similar to cavity substrate 106, but with port 820 extending partially through cavity substrate 806 in the vertical direction. For example, a portion of dielectric structure 840 and conductive structure 842 can be between port 820 and inner side 201 of substrate 102 and/or between port 820 and inner side 221 of substrate 104. Stated differently, a portion of side 841 and/or a portion of side 843 of cavity substrate 806 can vertically overlap port 820. Port 820 can fluidly connect die cavity 822 and the ambient environment external to electronic device 800. Port 820 can provide an opening through which sound fires out from electronic device 800. In some examples, electronic components 110 and 112 can generate sound that exits electronic device 800 through port 820.

FIG. 8B shows a top-down view of cavity substrate 806. In FIG. 8B, dotted lines are used to represent port 820, which is located under side 843. Cavity substrate 806 can include interior walls 824, 826, 828, and 830. Interior walls 824, 826, 828, and 830 can be selectively configured in location or thickness to control an accessible volume of port 820. Interior wall 824 can be oriented toward interior wall 826. Interior wall 828 can be oriented toward interior wall 830. Interior walls 828 and 830 can extend between interior wall 824 and interior wall 826. Interior wall 830 can include an opening, which provides an end (or inlet) of port 820. Exterior wall 832 of cavity substrate 806 can include an opening that provides an opposite end (or outlet) of port 820. FIG. 8A shows a cross-sectional view taken along line 8A-8A in FIG. 8B.

With combined reference to FIGS. 8A and 8B, cavity substrate 806 comprises dielectric structure 840 and conductive structure 842. Conductive structure 842 can include conductor 845 and terminals 844 provided along side 841 of cavity substrate 806. Conductive structure 842 can further include conductor 847 and terminals 846 provided along side 843 of cavity substrate 806. The elements, features, materials, or manufacturing methods of cavity substrate 806, dielectric structure 840, and conductive structure 842 can be similar to or the same as elements, features, materials, or manufacturing methods of cavity substrate 106, dielectric structure 240, and conductive structure 242, respectively.

Internal interconnects 250 can couple inner terminals 204 of substrate 102 to conductor 845 and terminals 844 of cavity substrate 806. Internal interconnects 252 can couple inner terminals 224 of substrate 104 to conductor 847 and terminals 846 of cavity substrate 806.

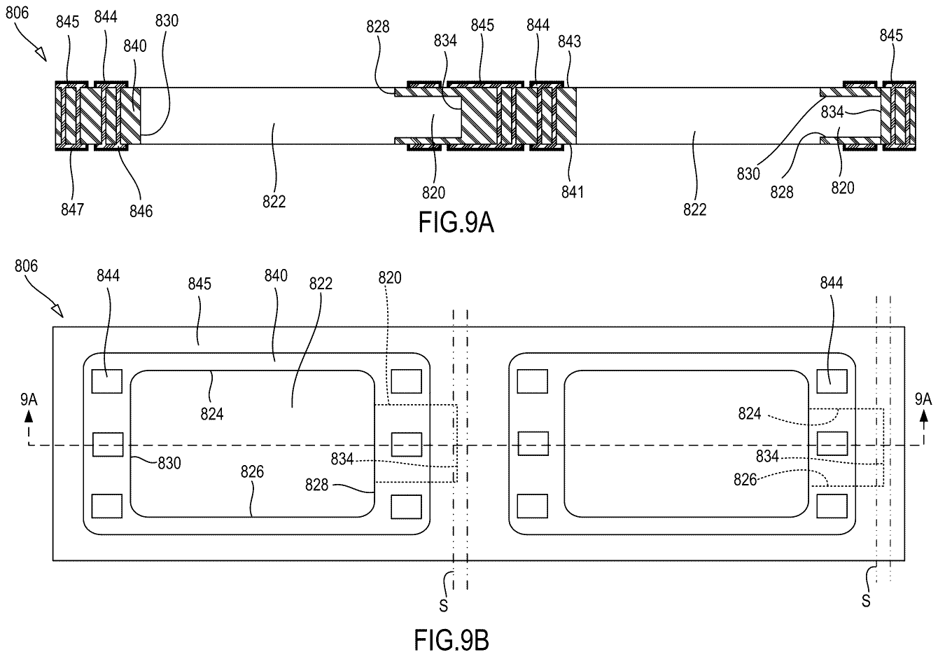

In some examples, port 820 can be opened in response to singulation. For example, and with reference to FIGS. 9A and 9B, a cross-sectional view and a top-down view, respectively, of cavity substrate 806 are shown prior to singulation of cavity substrate 806. FIG. 9A shows a cross-sectional view of cavity substrate 806 taken along line 9A-9A in FIG. 9B, in accordance with various examples.

In the example of FIG. 9B, features of port 820 are shown in dotted line, as port 820 is covered by side 841 in the top down view. Cavity substrate 806 can define side firing port 820 between a portion of interior sidewall 824 and a portion of interior sidewall 826. Port 820 can terminate at an inner wall 834 of cavity substrate 806. Inner wall 834 can be oriented toward interior sidewall 830. Inner wall 834 can extend between interior sidewall 824 and interior sidewall 826. Port 820 can be formed by milling, drilling, etching, or using other material removal or aperture forming techniques.

In accordance with various examples, saw street S can vertically overlap port 820 and inner wall 834. Port 820 can be opened in response to singulation. For example, adjacent cavity substrates 806 can be singulated by cutting through saw street S. During singulation, inner wall 834 can be removed, thereby forming exterior wall 832 (FIGS. 8A and 8B) and opening port 820. Once open, port 820 can fluidly connect die cavity 822 with an environment external to cavity substrate 806 and electronic device 800.

In various examples, the interior wall of dielectric structure 840 and the interior wall of dielectric structure 839 can partially define the entry to port 820. A distance between interior walls 828 and 830 can be selected to control a volume of air available in port 820. In some examples, port 820 can be in fluid communication with volume 117, port 116, die cavity 822, or port 118. In some examples, cavity substrate 806 can comprise multiple low-flow or no-flow prepregs cut prior to stack up and laminated, thereby allowing control of an air volume available in port 820 (e.g., by controlling the distance between interior walls 828 and 830). The height adjustment to port 820 made by controlling the distance between interior walls 828 and 830, for example, in concert with the height of cavity substrate 806. The height of port 820 in some examples can be substantially equal to the difference between the height of the cavity substrate 806 and the combined thickness of interior walls 828 and 830. In some examples, the volume of port 820 can also be controlled by selectively using multiple low-flow or no-flow prepregs cut prior to stack up and laminated to a desired thickness, thereby resulting in a desired thickness of side 841 and of side 843 vertically overlapping port 820. Increasing the thickness of side 841 or side 843 reduces the volume of port 820 available for air. Sidewalls of port 820 can also be spaced closer together or farther apart to control the volume of port 820.

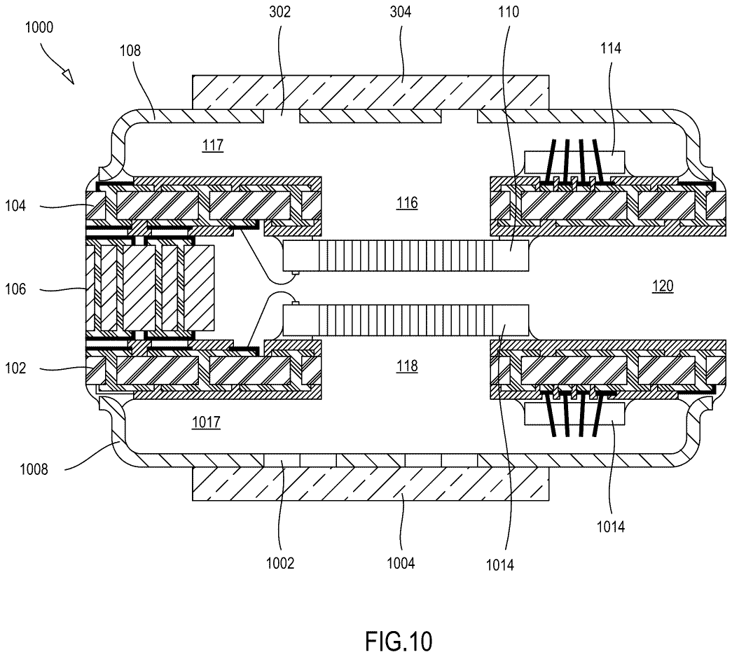

Referring now to FIG. 10, electronic device 1000 is shown, in accordance with various examples. Electronic device 1000 can be provided using materials and techniques similar to or the same as those of electronic device 100 (of FIGS. 1A-1D), or of other example devices described herein. Electronic device 1000 can include lid 1008 coupled to outer side 203 of substrate 102. Lid 1008 can define volume 1017 between lid 1008 and substrate 102. In some examples, an electronic component 1014 can be disposed in volume 1017 between substrate 102 and lid 1008. Electronic component 1014 can be coupled to outer terminals 206 of substrate 102.

In some examples, electronic component 1014 can be similar to electronic component 114. For example, electronic component 1014 can include an ASIC. Port 120 can be in fluid communication with volume 117, port 116, die cavity 122, port 118, or volume 1017. Lid 108 and lid 1008 can be coupled to opposite sides of electronic device 1000. For example, lid 108 can be coupled to outer side 223 of substrate 104, and lid 1008 can be coupled to outer side 203 of substrate 102. Lid 1008 can include apertures 1002 defined through the lid. In some examples, diaphragm 1004 can cover the apertures 1002 and can be coupled to lid 1008. Sound can exit through port 120.

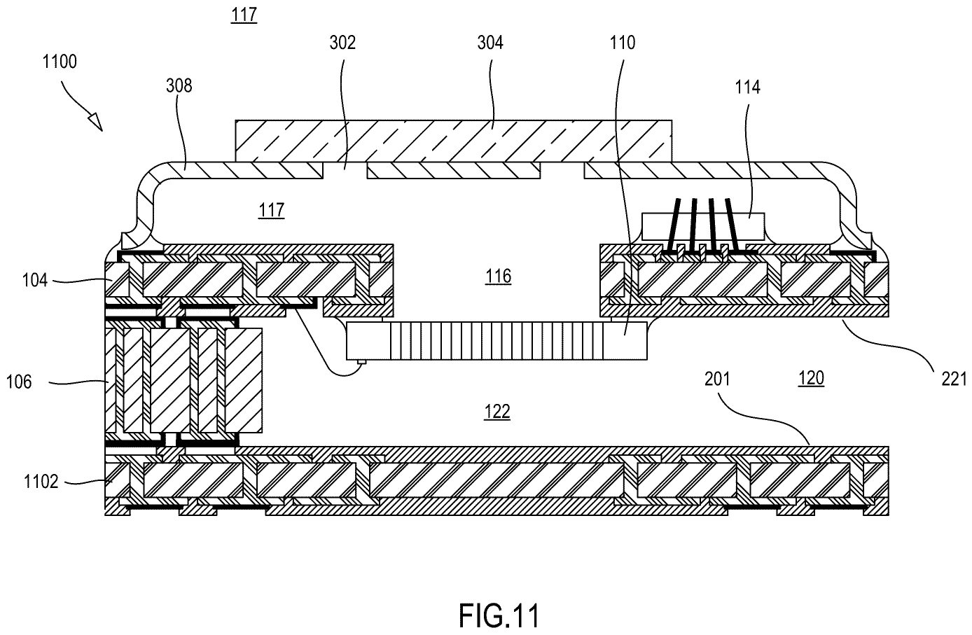

Referring now to FIG. 11, electronic device 1100 is shown, in accordance with various examples. Electronic device 1100 can be provided using materials and techniques similar to or the same as those of electronic device 1000 (of FIG. 10) or of other example devices described herein. Electronic device 1100 can include cavity substrate 806.

In some examples, cavity substrate 806 can define port 120 between a first interior sidewall 124 (of FIG. 2F) and a second interior sidewall 126 (of FIG. 2F). Port 120 can further be defined between inner side 221 of substrate 104 and inner side 201 of substrate 1102. Substrate 104 can comprise a smooth inner side 221 to define the upper bounds of port 120. Substrate 1102 can include a smooth inner side 201 to define the lower bounds of port 120. Although inner side 221 of substrate 104 and inner side 201 of substrate 1102 are depicted as smooth sides in the example of FIG. 11, substrates with uneven or varied sides can be included in various examples.

In various examples, port 120 can include an opening through which sound fires out from electronic device 1100. In some examples, electronic components 110 and 112 can generate sound that exits electronic device 1100 through port 120. Inner side 221 of substrate 104 and inner side 201 of substrate 1102 can be opposite one another and can directly face one another in various embodiments. A distance between inner side 221 and inner side 201 can be selected to control a volume of port 120. Port 120 can be in fluid communication with volume 117, port 116, die cavity 822, or port 118.

In some examples, electronic device 1100 can be provided using materials and techniques similar to or the same as those of electronic devices 100 (of FIGS. 1A-1D) and electronic device 300 (of FIG. 3A) or of other examples described herein. Electronic device 1100 can include substrate 1102 omitting port 118 (of FIG. 1B) through substrate 102 (of FIG. 1B). Port 120 of cavity substrate 106 can provide an opening through which sound fires out from electronic device 1100. In some examples, electronic component 110 can generate sound that exits electronic device 1100 through port 120. Port 120 can be in fluid communication with volume 117, port 116, or die cavity 122 in various examples.

In various examples, electronic devices and related methods of the present disclosure can improve audio performance and increase tuneability of MEMS speaker packages. One or more lids can define volume in fluid communication with MEMS speakers and tune audio characteristics. Apertures in the lid can enable interaction between the speakers and a diaphragm covering the apertures. A side-firing port can expel sound laterally from one or more MEMS speakers within a single electronic device. Various examples include laminate-to-laminate (L2L) structures having a smaller total device volume than some existing MEMS speaker packages.

The present disclosure includes reference to certain examples, however, it will be understood by those skilled in the art that various changes may be made and equivalents may be substituted without departing from the scope of the disclosure. Modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a first substrate defining a first port and comprising an inner side and an outer side;
a first electronic component including a first microelectromechanical system (MEMS) device disposed over the first port and coupled to the inner side of the first substrate;
a lid coupled to an outer side of the first substrate and defining a first volume between the lid and the first substrate, the first volume in fluid communication with the first port;
a cavity substrate defining a cavity and coupled to the inner side of the first substrate with the first electronic component extending into the cavity; and
a second substrate with an inner side of the second substrate coupled to the cavity substrate.

2. The electronic device of claim 1, wherein the second substrate defines a second port extending through the second substrate, wherein the second port is in fluid communication with the cavity.

3. The electronic device of claim 2, further comprising a second lid coupled to an outer side of the second substrate and defining a second volume between the second lid and the second substrate, the second volume in fluid communication with the second port.

4. The electronic device of claim 2, further comprising a second electronic component including a second MEMS device disposed over the second port and coupled to the inner side of the second substrate.

5. The electronic device of claim 1, wherein the cavity substrate defines a side port configured to fire sound generated by the first MEMS device.

6. The electronic device of claim 5, wherein the side port is defined by inner sidewalls of the cavity substrate, the inner side of the first substrate, and the inner side of the second substrate.

7. The electronic device of claim 5, wherein the side port is defined by inner sidewalls of the cavity substrate, an upper side of the cavity substrate, and a lower side of the cavity substrate.

8. The electronic device of claim 1, wherein the lid defines apertures extending through the lid, the apertures in fluid communication with the first volume between the lid and the first substrate.

9. The electronic device of claim 8, further comprising a diaphragm coupled to the lid and covering the apertures.

10. The electronic device of claim 1, further comprising a second electronic component disposed in the first volume between the first substrate and the lid, wherein the second electronic component is coupled to the outer side of the first substrate.

11. The electronic device of claim 1, further comprising a second electronic component disposed in the cavity defined by the cavity substrate, wherein the second electronic component is coupled to the inner side of the first substrate.

12. An electronic device, comprising:
a first substrate defining a first port;
a first electronic component including a first microelectromechanical system (MEMS) speaker disposed over the first port and coupled to an inner side of the first substrate;
a cavity substrate defining a cavity and a side port, the cavity substrate coupled to the inner side of the first substrate with the first electronic component extending into the cavity; and
a second substrate having an inner side of the second substrate coupled to the cavity substrate opposite the first substrate.

13. The electronic device of claim 12, wherein the second substrate defines a second port in fluid communication with the cavity.

14. The electronic device of claim 12, further comprising a lid coupled to an outer side of the first substrate and defining a volume in fluid communication with the first port.

15. The electronic device of claim 12, further comprising a second electronic component including a second MEMS speaker coupled to the inner side of the second substrate.

16. The electronic device of claim 12, wherein the side port is defined by inner sidewalls of the cavity substrate, the inner side of the first substrate, and the inner side of the second substrate.

17. The electronic device of claim 12, wherein the side port is defined by inner sidewalls of the cavity substrate, an upper side of the cavity substrate, and a lower side of the cavity substrate.

18. The electronic device of claim 12, further comprising a second electronic component disposed in the cavity defined by the cavity substrate, wherein the second electronic component is coupled to the inner side of the first substrate adjacent the first electronic component.

19. A method of making an electronic device, comprising:
providing a first substrate defining a port;
coupling an electronic component to an inner side of the first substrate, the electronic component including a first microelectromechanical system (MEMS) device and disposed over the port;
coupling a cavity substrate to the inner side of the first substrate, wherein the electronic component extends into a cavity; and
coupling a second substrate to the cavity substrate opposite the first substrate; and
coupling a first lid to an outer side of the first substrate, wherein a first volume is defined between the first lid and the first substrate, wherein the volume is in fluid communication with the port.

20. The method of claim 19, further comprising coupling a second lid to an outer side of the second substrate, wherein a second volume is defined between the second lid and the second substrate, wherein the second volume is in fluid communication with the port.
